(19) United States
(12) Patent Application Publication
(10) Pub. No.: US 2019/0040316 A1
(43) Pub. Date: Feb. 7, 2019

(54) ETCHING SOLUTION OF IGZO FILM LAYER AND ETCHING METHOD OF THE SAME

(71) Applicant: Shenzhen China Star Optoelectronics Semiconductor Display Technology Co., Ltd., Shenzhen City GD (CN)

(72) Inventor: Qiming Gan, Shenzhen City (CN)

(21) Appl. No.: 15/579,936

(22) PCT Filed: Nov. 16, 2017
(86) PCT No.: PCT/CN2017/111362

§ 371 Date: Dec. 5, 2017

(30) Foreign Application Priority Data
Aug. 4, 2017 (CN) 201710662486.9

(51) Int. Cl. C09K 13/06; H01L 21/027; H01L 21/465; H01L 21/467; H01L 29/66; H01L 29/24; H01L 29/786; H01L 27/12

(52) U.S. Cl. CPC C09K 13/06; H01L 21/0274; H01L 21/465; H01L 21/467; H01L 27/1225; H01L 29/24; H01L 29/7869; H01L 27/127; H01L 27/1288; H01L 29/66969

(57) ABSTRACT

The present invention provides an etching solution of IGZO film layer and an etching method of the same. The etching solution of IGZO film layer of the present invention comprises an acid, a phosphate, a hydrogen peroxide, and water; and the PH value of the etching solution of IGZO film layer is no more than 5, which are capable of effectively controlling the rate of the etching solution to make the etching rate uniform, then the IGZO film layer is etched stably without introducing impurities affecting the electric characteristic of the IGZO, to raise the stability of the IGZO-TFT device. The etching method of IGZO film layer, with applying the etching solution mentioned above, which is capable of effectively controlling the rate of the etching solution to make the etching rate uniform, then the IGZO film layer, is etched stably without introducing impurities affecting the electric characteristic of the IGZO, to raise the stability of the IGZO-TFT device.

### BACKGROUND OF THE INVENTION

### Field of Invention

The present invention relates to the field of manufacturing the display panel, and more particularly to an etching solution of IGZO film layer and an etching method of the same.

### Description of Prior Art

With the development of display technology, the liquid crystal display panel is gradually developed towards large-size and high-resolution, which means that the charging time of the pixel also becomes shorter and shorter, and the thin film transistor (TFTs) inside the display panel play an important role for pixel charging. However, the characteristic of the TFTs are mainly decided by the properties of the active layer. Conventional TFT devices usually use amorphous silicon (a-Si, AS) as an active layer. AS-TFT devices have been developed for a long time and the device characteristics are stable. However, the mobility of AS is low and its advantages are gradually lost under the development trend of high-resolution and high refresh rate. Another semiconductor material, Indium Gallium Zinc Oxide (IGZO), is praised by people for its advantages of high mobility and suitable for large-area production, and has become a hot spot in the field of TFT technology. IGZO has a larger mobility than AS, so that the TFT can have a faster charging rate, and the TFT can be made smaller to further improve the pixel aperture ratio and reduce the backlight consumption. On the other hand, IGZO-TFT device has small leakage current itself, which is also an advantage for the power consumption of the LCD panel itself.

However, the current IGZO-TFT device still needs to be improved in stability. The IGZO active layer is very sensitive to the process and the environment. The IGZO active layer is easily affected by light, temperature and the like, such as the Q-time (a time interval between IGZO process is finished and a next site), in the IGZO process, the IGZO active layer is particularly affected by the IGZO etchant, such as the etchant etching uniformity, whether some conductive impurities are introduced to the etchant, etc., causing a great impact on the IGZO-TFT device stability, such as leading to abnormalities such as IGZO Vth (starting voltage) drift or leakage current.

### SUMMARY OF THE INVENTION

An object of the present invention is to provide an etching solution of IGZO film layer, which is capable of effectively controlling the rate of the etching solution to make the etching rate uniform, then the IGZO film layer is etched stably without introducing impurities affecting the electric characteristic of the IGZO, to raise the stability of the IGZO-TFT device.

An object of the present invention is to provide an etching method of IGZO film layer, with applying the etching solution mentioned above, which is capable of effectively controlling the rate of the etching solution to make the etching rate uniform, then the IGZO film layer is etched stably without introducing impurities affecting the electric characteristic of the IGZO, to raise the stability of the IGZO-TFT device.

In order to achieve the object, the present invention provides an etching solution of IGZO film layer, which comprises an acid, a phosphate, a hydrogen peroxide, and water. A PH value of the etching solution of IGZO film layer is no more than 5.

Among the etching solution of IGZO film layer, a mass percentage of the acid is 2% to 5%, a mass percentage of the phosphate is 5% to 10%, a mass percentage of the hydrogen peroxide is 15% to 22%, and rest is the water.

The acid is a mixed acid of an inorganic acid and an organic acid.

The inorganic acid is phosphoric acid. The organic acid is selected from at least one from the group consisting of acetic acid, oxalic acid, and oxalic acid.

The phosphate is selected from at least one from the group consisting of dihydrogen phosphate and hydrogen phosphate.

The dihydrogen phosphate is sodium dihydrogen phosphate and the hydrogen phosphate is disodium phosphate.

The PH value of the etching solution of IGZO film layer is 3 to 5.

The present invention further provides an etching method of an IGZO film layer, which comprises: the IGZO film layer is contacted with the etching solution of IGZO film layer as mentioned above.

A temperature of the etching solution of IGZO film layer is between 20° C. to 45° C.

The etching method to the IGZO film layer is applied for a patterning process, to derive an IGZO pattern.

The present invention provides another etching solution of IGZO film layer, which comprises an acid, a phosphate, a hydrogen peroxide, and water. A PH value of the etching solution of IGZO film layer is no more than 5.

Wherein among the etching solution of IGZO film layer, a mass percentage of the acid is 2% to 5%, a mass percentage of the phosphate is 5% to 10%, a mass percentage of the hydrogen peroxide is 15% to 22%, and rest is the water.

Wherein the acid is a mixed acid of an inorganic acid and an organic acid.

Wherein the inorganic acid is phosphoric acid, the organic acid is selected from at least one from the group consisting of acetic acid, oxalic acid, and oxalic acid.

Wherein the phosphate is selected from at least one from the group consisting of dihydrogen phosphate and hydrogen phosphate.

The beneficial effects of the present invention are: the etching solution of IGZO film layer of the present invention comprises an acid, a phosphate, a hydrogen peroxide, and water; and the PH value of the etching solution of IGZO film layer is no more than 5, which are capable of effectively controlling the rate of the etching solution to make the etching rate uniform, then the IGZO film layer is etched stably without introducing impurities affecting the electric characteristic of the IGZO, to raise the stability of the IGZO-TFT device. The etching method of IGZO film layer, with applying the etching solution mentioned above, which is capable of effectively controlling the rate of the etching solution to make the etching rate uniform, then the IGZO film layer, is etched stably without introducing impurities affecting the electric characteristic of the IGZO, to raise the stability of the IGZO-TFT device.

For further understanding of the features and technical contents of the present invention, reference should be made to the following detailed description and accompanying drawings of the present invention. However, the drawings are for reference only and are not intended to limit the present invention.

### BRIEF DESCRIPTION OF THE DRAWINGS

The technical solutions of the present invention and other beneficial effects will be apparent from the following detailed description of specific embodiments of the present invention with reference to the accompanying drawings.

In drawings:

FIG. 1 is a flow chart of patterning an IGZO film layer by an etching method of an IGZO film layer according to the present invention.

FIG. 2-3 are illustrative diagrams of the step S1 of patterning the IGZO film layer by the etching method of the IGZO film layer according to the present invention.

FIG. 4-5 are illustrative diagrams of the step S2 of patterning the IGZO film layer by the etching method of the IGZO film layer according to the present invention.

### DETAILED DESCRIPTION OF THE PREFERRED EMBODIMENTS

The technical means and the effects thereof will be further described with reference to the preferred embodiments of the present invention and their accompanying drawings.

The present invention provides an etching solution of IGZO film layer, which comprises an acid, a phosphate, a hydrogen peroxide, and water. A PH value of the etching solution of IGZO film layer is no more than 5.

Among the etching solution of IGZO film layer, a mass percentage of the acid is 2% to 5%, a mass percentage of the phosphate is 5% to 10%, a mass percentage of the hydrogen peroxide is 15% to 22%, and rest is the water.

Specifically, the acid is a mixed acid of an inorganic acid and an organic acid.

Furthermore, the inorganic acid is phosphoric acid. The organic acid is selected from at least one from the group consisting of acetic acid, oxalic acid, and oxalic acid.

Specifically, the phosphate is selected from at least one from the group consisting of dihydrogen phosphate and hydrogen phosphate.

Furthermore, the dihydrogen phosphate is sodium dihydrogen phosphate and the hydrogen phosphate is disodium phosphate.

Preferably, the PH value of the etching solution of IGZO film layer is 3 to 5.

The etching solution of IGZO film layer of the present invention is capable of effectively controlling the rate of the etching solution to make the etching rate uniform, then the IGZO film layer is etched stably without introducing impurities affecting the electric characteristic of the IGZO, to raise the stability of the IGZO-TFT device.

Based on the etching solution of the IGZO film layer as mentioned above, the present invention further provides an etching method of an IGZO film layer, which comprises: the IGZO film layer is contacted with the etching solution of IGZO film layer as mentioned above.

Specifically, a temperature of the etching solution of IGZO film layer is between 20° C. to 45° C. In other words, the IGZO film layer is contacted with the etching solution of IGZO film layer when the temperature is between 20° C. to 45° C.

Specifically, the etching method to the IGZO film layer is applied for a patterning process, to derive an IGZO pattern.

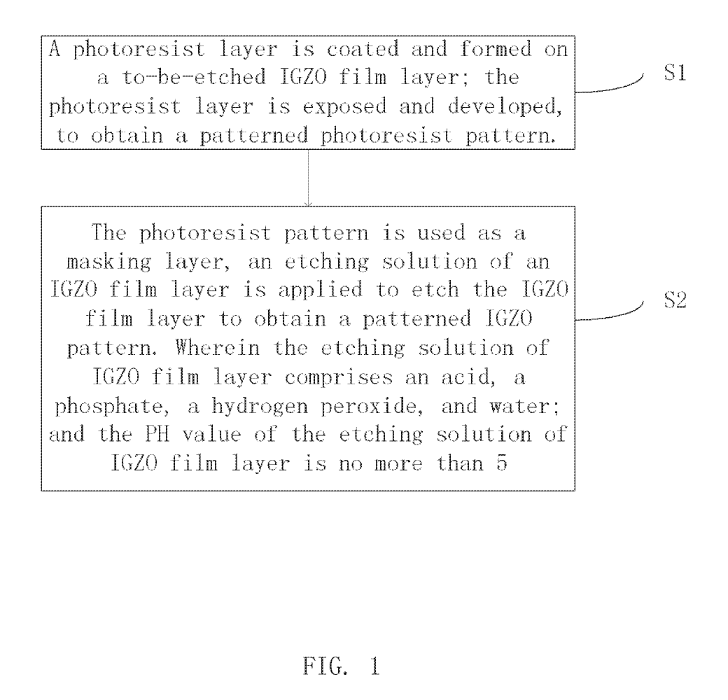

Furthermore, please refer to FIG. 1, a flow chart of patterning an IGZO film layer by an etching method of an IGZO film layer according to the present invention specifically comprises below steps:

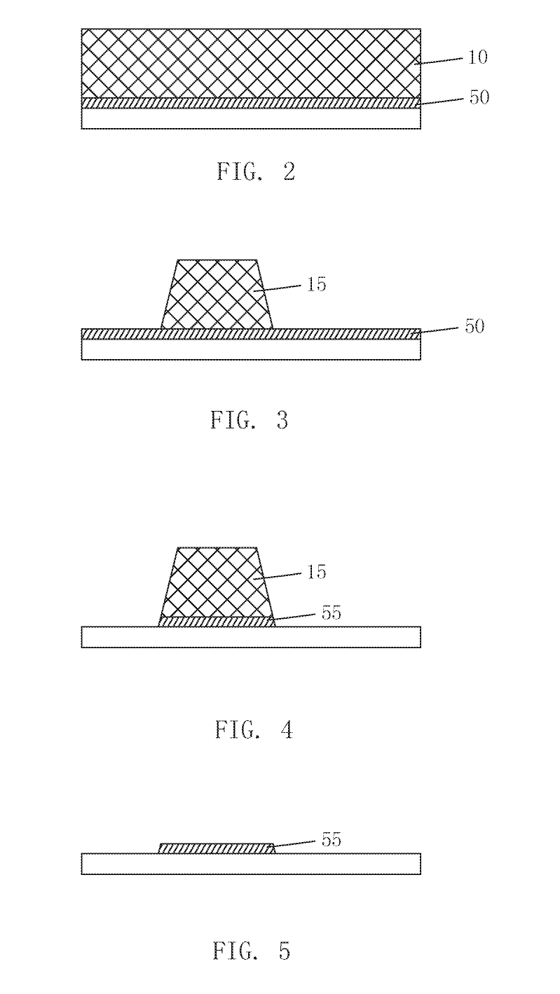

Step S1, as shown in FIGS. 2-3, a photoresist layer 10 is coated and formed on a to-be-etched IGZO film layer 50; the photoresist layer 10 is exposed and developed, to obtain a patterned photoresist pattern 15.

Step S2, as shown in FIGS. 4-5, the photoresist pattern 15 is used as a masking layer, an etching solution of an IGZO film layer is applied to etch the IGZO film layer 50 when the temperature is between 20° C. to 45° C., and at this time, the IGZO film layer 50 which is not covered with the photoresist pattern 15 is etched away by contacting with the etching solution of the IGZO film layer, and the IGZO film layer 50 which is covered with the photoresist pattern 15 is left to obtain a patterned IGZO pattern 55, then, the photoresist pattern 15 covered on the IGZO pattern 55 is removed.

The etching method of IGZO film layer of the present invention applies the etching solution mentioned above, which is capable of effectively controlling the rate of the etching solution to make the etching rate uniform, then the IGZO film layer is etched stably without introducing impurities affecting the electric characteristic of the IGZO, to raise the stability of the IGZO-TFT device.

As mentioned above, the etching solution of IGZO film layer of the present invention comprises an acid, a phosphate, a hydrogen peroxide, and water; and the PH value of the etching solution of IGZO film layer is no more than 5, which are capable of effectively controlling the rate of the etching solution to make the etching rate uniform, then the IGZO film layer is etched stably without introducing impurities affecting the electric characteristic of the IGZO, to raise the stability of the IGZO-TFT device. The etching method of IGZO film layer, with applying the etching solution mentioned above, which is capable of effectively controlling the rate of the etching solution to make the etching rate uniform, then the IGZO film layer, is etched stably without introducing impurities affecting the electric characteristic of the IGZO, to raise the stability of the IGZO-TFT device.

As mentioned above, those of ordinary skill in the art, without departing from the spirit and scope of the present invention, can make various kinds of modifications and variations to the present invention. Therefore, all such modifications and variations are intended to be included in the protection scope of the appended claims of the present invention.

What is claimed is:

1. An etching solution of IGZO film layer, comprising an acid, a phosphate, a hydrogen peroxide, and water; a PH value of the etching solution of IGZO film layer being no more than 5.

2. The etching solution of IGZO film layer according to claim 1, wherein among the etching solution of IGZO film layer, a mass percentage of the acid is 2% to 5%, a mass percentage of the phosphate is 5% to 10%, a mass percentage of the hydrogen peroxide is 15% to 22%, and rest is the water.

3. The etching solution of IGZO film layer according to claim 1, wherein the acid is a mixed acid of an inorganic acid and an organic acid.

4. The etching solution of IGZO film layer according to claim 3, wherein the inorganic acid is phosphoric acid, the organic acid is selected from at least one from the group consisting of acetic acid, oxalic acid, and oxalic acid.

5. The etching solution of IGZO film layer according to claim 1, wherein the phosphate is selected from at least one from the group consisting of dihydrogen phosphate and hydrogen phosphate.

6. The etching solution of IGZO film layer according to claim 5, wherein the dihydrogen phosphate is sodium dihydrogen phosphate and the hydrogen phosphate is disodium phosphate.

7. The etching solution of IGZO film layer according to claim 1, wherein the PH value of the etching solution of IGZO film layer is 3 to 5.

8. An etching method of an IGZO film layer, comprising contacting the IGZO film layer with the etching solution of IGZO film layer according to claim 1.

9. The etching method of IGZO film layer according to claim 8, wherein a temperature of the etching solution of IGZO film layer is between 20° C. to 45° C.

10. The etching method of IGZO film layer according to claim 8, wherein applying the etching method to the IGZO film layer for a patterning process, to derive an IGZO pattern.

11. An etching solution of IGZO film layer, comprising an acid, a phosphate, a hydrogen peroxide, and water; a PH value of the etching solution of IGZO film layer being no more than 5;
wherein among the etching solution of IGZO film layer, a mass percentage of the acid is 2% to 5%, a mass percentage of the phosphate is 5% to 10%, a mass percentage of the hydrogen peroxide is 15% to 22%, and rest is the water;
wherein the acid is a mixed acid of an inorganic acid and an organic acid;
wherein the inorganic acid is phosphoric acid, the organic acid is selected from at least one from the group consisting of acetic acid, oxalic acid, and oxalic acid;
wherein the phosphate is selected from at least one from the group consisting of dihydrogen phosphate and hydrogen phosphate.

12. The etching solution of IGZO film layer according to claim 11, wherein the dihydrogen phosphate is sodium dihydrogen phosphate and the hydrogen phosphate is disodium phosphate.

13. The etching solution of IGZO film layer according to claim 11, wherein the PH value of the etching solution of IGZO film layer is 3 to 5.
